(19) United States
(12) Patent Application Publication
(10) Pub. No.: US 2007/0164264 A1
(43) Pub. Date: Jul. 19, 2007

(54) Storage system using an array of electro-magnetic sensors

(76) Inventors: Kars-Michiel Hubert Lenssen, Eindhoven (NL); Hendrik Van Houten, Eindhoven (NL)

Correspondence Address: PHILIPS INTELLECTUAL PROPERTY & STANDARDS, P.O. BOX 3001, BRIARCLIFF MANOR, NY, 10510, US

(21) Appl. No.: 10/529,680

(22) PCT Filed: Sep. 30, 2003
(86) PCT No.: PCT/IB03/04312

§ 371 Date: Feb. 6, 2007

(30) Foreign Application Priority Data
Oct. 3, 2002 (EP) 02079078.8
Dec. 30, 2002 (EP) 02080595.8

(51) Int. Cl. H01L 47/00

(52) U.S. Cl. 257/1

(57) ABSTRACT

A record carrier (40) of a removable type has an information plane that is provided with a pattern of an electro-magnetic material constituting an array of bit locations (11). The presence or absence of said material at the information plane represent the value of a bit location. The device has an interface surface (32) for cooperating with the information plane. The interface surface is provided with an array of electro-magnetic sensor elements (54,56) that are sensitive to the presence of said electro-magnetic material within a near-field working distance. The record carrier and device system have alignment means (38,41) for positioning the bit locations near the sensor elements within the near-field working distance between a bit location and the corresponding sensor when the record carrier is mounted in the device.

The invention relates to a storage system comprising a record carrier and a storage device, the record carrier having an information plane that is provided with a pattern of an electromagnetic material constituting an array of bit locations.

The invention further relates to a record carrier comprising an information plane that is provided with a pattern of an electromagnetic material constituting an array of bit locations, and a storage device for use in the system.

A storage system, record carrier, and a device for storing information are known from patent U.S. Pat. No. 5,956,216. Data storage systems using magnetic material on a disc-type record carrier are well known, for example a removable type magnetic record carrier like the floppy disk. The document describes a magnetic record carrier of a patterned type. The record carrier has an information plane that is provided with a magnetic layer that can be magnetized by a suitable magnetic field from a write head. In particular the information plane is provided with a non-magnetic substrate and magnetic domain elements that can have two magnetization values. The magnetic domain elements constitute bit locations for storing a single bit of data. The device has a head and a write unit for recording information in a track constituted by the bit locations on the record carrier. The value of a bit location must be set or retrieved by positioning a read/write head opposite the bit location, e.g. by scanning the track. A problem of the known magnetic storage system is that the scanning does not allow random access to any bit location. The process of storing data in the bit locations and of positioning the head via a jump to a required part of the track is time consuming.

Therefore it is an object of the invention to provide a system comprising a record carrier and a device for storing information efficiently at the bit locations and that allows fast access to the bit locations.

According to a first aspect of the invention the object is achieved with a storage system as defined in the opening paragraph, the presence or absence of said material at the information plane representing a value of a bit location, and the device having an interface surface for cooperating with the information plane, which interface surface is provided with an array of electromagnetic sensor elements that are sensitive to the presence of said electromagnetic material within a near-field working distance, which record carrier can be coupled to and removed from the storage device, and the system having alignment means for positioning the bit locations near the sensor elements within the near-field working distance between a bit location and the corresponding sensor element during said coupling.

According to a second aspect of the invention the object is achieved with a record carrier as defined in the opening paragraph, characterized in that the presence or absence of said material at the information plane represents a value of a bit location, and in that the record carrier comprises alignment means for positioning the bit locations near the sensor elements within a near-field working distance between a bit location and the corresponding sensor element during said coupling.

According to a third aspect of the invention the object is achieved with a storage device as defined in the opening paragraph, characterized in that the device comprises an interface surface for cooperating with the information plane, which interface surface is provided with an array of electro-magnetic sensor elements that are sensitive to the presence of said electro-magnetic material, and alignment means for positioning the sensor elements near the bit locations within a near-field working distance between a sensor element and the corresponding bit location during said coupling.

The effect of the presence or absence of said material at the information plane representing a value of a bit location is, that a fixed pattern of material can be applied to the record carrier in a low-cost manufacturing process, e.g. by mechanically embossing a pattern. The effect of an array constituted by electromagnetic sensor elements cooperating with the information plane is that data from a large number of bit locations can be retrieved simultaneously. This has the advantage that data can be distributed at a low cost and that data can be accessed at a high speed.

The invention is also based on the following recognition. The known magnetic storage system provides a record carrier that can be recorded by magnetizing a material in a layer or pattern in a user recording device. Further the well known optical discs that provide cheap data distribution are relatively slow and large, and require a scanning mechanism which is sensitive to mechanical shocks. The solid state memory devices like EPROM and MRAM are expensive per bit. The inventors have seen that a new class of storage that combines several advantageous properties of the previous systems can be provided by a record carrier having a pattern of electromagnetic material on a substrate. Such record carrier can be cheaply produced using known manufacture techniques. The material is called electro-magnetic because its presence or absence is detectable via an electrical and/or magnetic field (also called bias field). It is noted that the detection of the value of a bit location does not depend on the magnetic state of the material, but on the presence or absence of the material itself. The electromagnetic element detects disturbances in the bias field within a predefined near-field working distance, which is in practice in the same order of magnitude as the minimum dimensions of the bit location. Alignment is required to bring the elements opposite and close to the bit locations within the near-field working distance. In particular the alignment is different from a scanning system in that the array is aligned parallel to the information plane and also in height with respect to the information plane. Suitable electromagnetic elements can be produced using solid state production methods, e.g. known from producing MRAM magnetic storage devices.

In an embodiment of the record carrier the pattern at the information plane is constituted by a layer of the electromagnetic material on the substrate having protruding or depressed portions that bring the electromagnetic material of the layer either outside or inside the near-field working distance. This has the advantage that the record carrier is easily producible using mechanical replication techniques like stamping.

Further preferred embodiments of the record carrier and the storage device according to the invention are given in the dependent claims.

These and other aspects of the invention will be apparent from and elucidated further with reference to the embodiments described by way of example in the following description and with reference to the accompanying drawings, in which

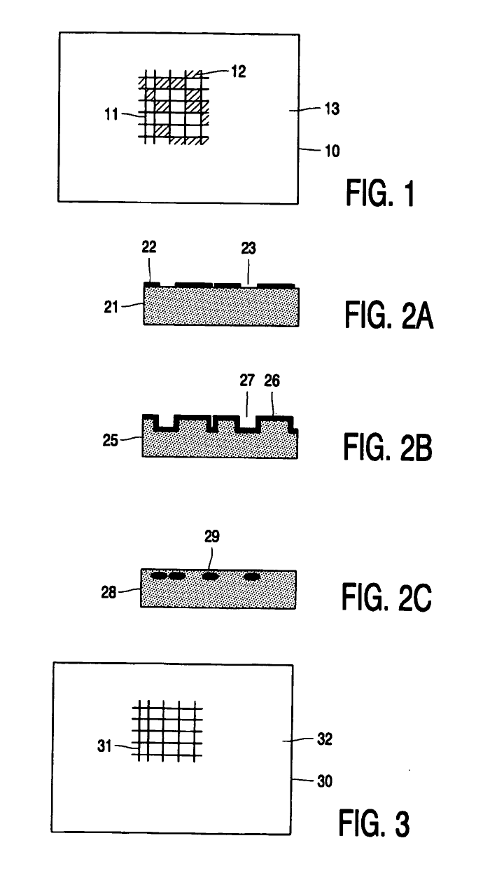

FIG. 1 shows an information carrier part (top view),

FIG. 2a shows a patterned information carrier part,

FIG. 2b shows an embossed information carrier part,

FIG. 2c shows an information carrier part having embedded particles,

FIG. 3 shows a read-out part,

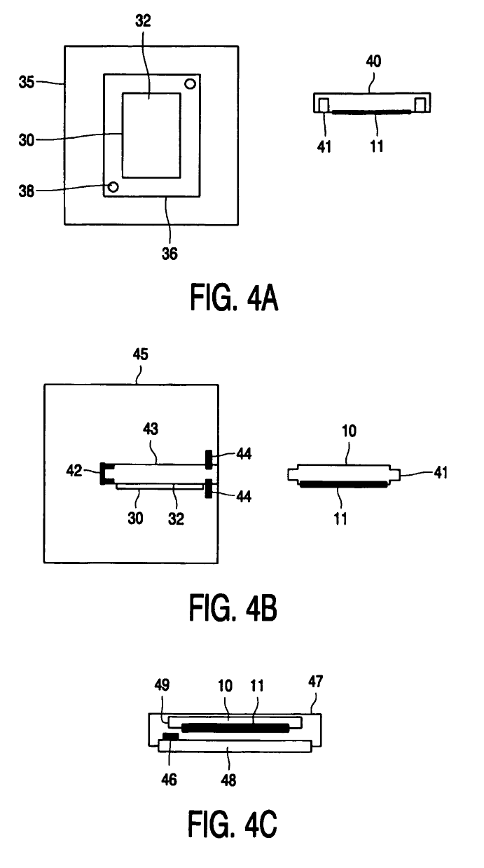

FIG. 4a shows a storage device (top view) and record carrier,

FIG. 4b shows a storage device (side view) and record carrier,

FIG. 4c shows a record carrier in a cartridge,

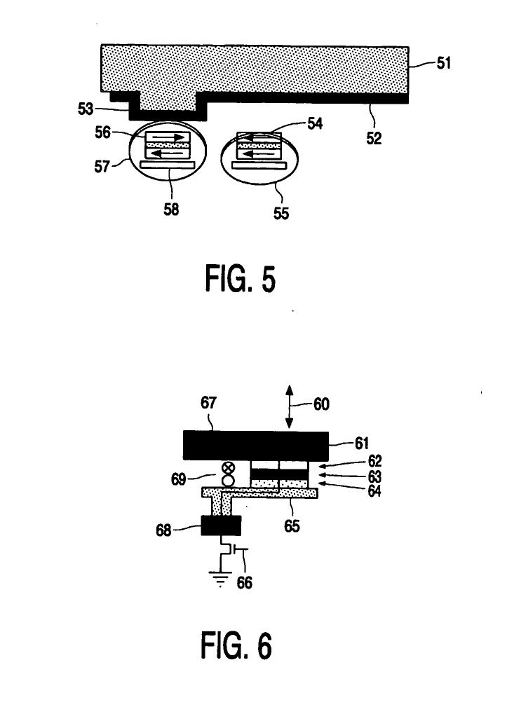

FIG. 5 shows a sensor elements at a near field working distance of an information plane, and

FIG. 6 shows a sensor element in detail.

In the Figures, elements which correspond to elements already described have the same reference numerals.

FIG. 1 shows an information carrier part (top view). An information carrier part 10 has an information plane that is provided with a pattern of an electromagnetic material 12 constituting an array of bit locations 11. The presence or absence of the material 12 at the information plane provides a physical parameter for representing a value of a bit location. It is noted that the information plane is situated on a top surface 13 of the information carrier part 10. The top surface 13 of the information carrier part is intended to be coupled to an interface surface of a read-out part. The information plane is considered to be present at an effective distance from the mechanical top layer, e.g. a thin cover layer for protecting the information plane may constitute the outer layer of the information carrier part. Further it is noted that material away from the top surface 13 and outside a near-field working distance of an intended read-out part is not considered part of the information plane. Sensor elements in said read-out part are placed near the information plane, but some intermediate material like contamination may be present in between. Hence the effective distance is determined by any intermediate material and the intended read-out sensor elements that have a near-field working distance extending outward from the interface surface towards the information plane. The physical effect of the presence or absence of material at the information plane for reading the information is explained below with reference to FIG. 5.

FIG. 2a shows a patterned information carrier part in a cross section view. The information carrier has a substrate 21. An information plane is constituted on the top side of the substrate 21 by a pattern of electro-magnetic material, the pattern constituting an array of bit locations. In a first bit location 22 the material is present for example indicating the logic value 1, and in a second bit location 23 the material is absent for example indicating a logic value 0. The material has a soft magnetic property for being detectable by said sensor elements. The pattern of material can be applied by well known manufacturing methods for patterned magnetic media, although it is to be noted that no permanent magnetizations are required. Suitable methods are sputtering and locally etching, ion beam patterning or pressing using a mask.

FIG. 2b shows an embossed information carrier part in a cross section view. The information carrier has a substrate 25. An information plane is constituted on the top side of the substrate 25 by a continuous layer of electromagnetic material that has protruding and depressed portions. The shape of the layer constitutes an array of bit locations. In a first bit location 26 the material is present by a protruding portion within the near-field working distance of the intended read-out unit, for example indicating the logic value 1. In a second bit location 27 the material is absent from the information plane by a depressed portion which brings the material outside the near-field working distance, for example indicating a logic value 0. The embossed pattern can be applied to the substrate (or to the layer itself) by well known manufacturing methods, like pressing using a stamp similar to producing optical discs of the CD type. For example for production first fabricate a resist mask on a bare Si wafer by means of electron-beam lithography and use this as a master. If desired, holes are etched in the Si for storing the information in the 2D hole pattern. Then, using the master, replicate the pattern on a foil, or via injection moulding, or via embossing, or via 2P. Then deposit a thin magnetic layer (e.g. via sputtering) on the replica, and, optionally, magnetize the material in a uniform external magnetic field. It is to be noted that there are various possibilities for the exact operation principle. The information plane merely functions as a flux guide (using soft-magnetic material, and hence no magnetization step required); the information plane uses shape anisotropy, resulting e.g. in a perpendicular magnetization of the inverted holes; or the information plane has been magnetized uniformly, resulting in stray fields at the edges of the holes. The first principle, as further described with FIG. 5, has the advantage that it is most simple to realize, and it circumvents the limitations on bit size imposed by the super paramagnetic limit.

FIG. 2c shows an information carrier part having embedded particles in a cross section view. The information carrier has a substrate 28. An information plane is constituted at the top side of the substrate 28 by embedding particles 29. At a bit location there is either a particle of the material embedded or no particle, indicating the logical value. The particles present the material within the near-field working distance of the intended read-out unit. Obviously, instead of embedding a single particle at a bit location, a number of smaller particles may be used also. The information carrier is manufactured by incorporating a pattern of beads in the substrate or attaching beads to the substrate using a glue mask. Alternatively the beads can be positioned by applying spatially modulated magnetic fields.

FIG. 3 shows a read-out part. The read-out part 30 is intended to cooperate with the information carrier parts described above. Thereto the read-out part has an interface surface 32. The interface surface 32 is provided with an array 31 of sensor elements. The array is a two-dimensional layout of electromagnetic sensor units that are sensitive to the presence of said electromagnetic material on a near-field working distance.

It is noted that several combinations of an electromagnetic material and a sensor element can be chosen. In an embodiment the sensor elements are provided with circuitry for generating a magnetic field and detecting the magnetic field as influenced by the presence of absence of the material having a soft magnetic property. In another embodiment the sensor elements are provided with circuitry for generating an electrical field and detecting the electrical field as influenced by the presence or absence of the electromagnetic material, e.g. via capacitive coupling. In another embodiment the sensor elements are provided with circuitry for generating a fluctuating magnetic field and detecting the magnetic field as influenced by the presence of absence of a conductive material via eddy currents. In another embodiment the sensor elements are arranged for emitting light as the electromagnetic field and detecting the effect of the material on a near-field working distance from the source of light. The further embodiments described below are based on using magnetic material. A suitable material is a soft magnetic material and a suitable sensor element is based on the magneto-resistive effect. An example is described below with reference to FIG. 6.

FIG. 4a shows a storage device (top view) and record carrier. The storage device has a housing 35 and an opening 36 for receiving a record carrier 40.

The record carrier 40 includes an information carrier part 10 that has an information plane that has an array of bit locations 11 as described above with reference to FIGS. 1 and 2.

Further the record carrier has alignment elements 41 for cooperating with the complementary alignment elements 38 on the device for positioning the bit locations near the sensor elements within the near-field working distance between a bit location and the corresponding sensor element during said coupling. Read-out of the record carrier is realized by providing appropriate alignment and registration during insertion of the medium in the reader device as described below. In an embodiment the alignment elements are predefined and precisely shaped parts of the outer walls of the information carrier part. It is noted that the record carrier can be substantially only the information carrier part as described above, or an assembly containing an information carrier part. For example a single substrate carrying the 30 information plane is further shaped to accommodate the several types of alignment elements as described hereafter.

When coupling the record carrier 40 to the storage device 35 the record carrier is placed on the opening 36. The opening 36 is provided with an interface surface 32 on a read-out unit 30 as described above with reference to FIG. 3, and with alignment elements 38, for example protruding pins. The alignment elements 38, 41 are arranged for determining the position of the bit locations on the record carrier with respect to the position of the interface surface of the read-out unit 30 in planar directions parallel to the interface surface.

In an embodiment the opening 36 is a recess in the surface of the housing, the recess having precisely shaped walls as alignment elements for cooperating with the outer perimeter of the record carrier 40 for aligning the information carrier part.

In an embodiment the storage device is provided with processing circuitry for analyzing the read-out signals of the sensor elements for eliminating influences of neighboring bit locations. Any sensor element may be influenced somewhat by adjacent bit locations, in particular due to some remaining misalignment. However, by analyzing the read-out signals of neighboring sensor elements and subtracting some of those from the current read-out signal, the detected value of the current bit location is improved. Hence electronic correction of inter-symbol interference is provided. The analysis may be controlled by global information about the remaining misalignment, for example indicating which of the neighboring read-out signals must be subtracted and to which extent.

In the direction perpendicular to the interface surface some pressure is required to make sure that the distance of the bit locations to the sensor elements in the read-out part is within the near-field working distance. The pressure may be provided by a user just pressing the record carrier to the storage device, or by a resilient lid or cover on top of the record carrier (not shown). Other options for achieving close physical contact are well-known to a skilled man.

In an embodiment of the record carrier the information plane is provided on a flexible substrate. The device is provided with a pressure system for bringing the flexible substrate in close contact with the interface surface, for example by creating a low pressure or vacuum between the substrate and the interface surface. In an embodiment the device is provided with a generator for generating an attracting field for attracting the information carrier to the interface surface. The type of attracting field is different from the field used by the sensor element. For example an electrostatic field is generated for attracting a record carrier of a magnetic type. Alternatively a magnetic field is generated for a record carrier based on capacitive read-out.

In an embodiment the alignment elements 38 on the device are connected to actuators for moving the record carrier with respect to the interface surface 32. Only a small movement, in the order of magnitude of the dimensions of a single bit location (i.e. a few μm or less), is sufficient to align the sensor elements with the bit locations. For the actuators several types may be used, e.g. voice coil type, piezo type or electrostatic type. In an embodiment the actuators are controlled by detecting misalignment of the bit locations. The misalignment can be derived from read-out signals of the sensor elements. For example if there is a substantial misalignment the sensor elements will cover adjacent bit locations. Read-out signals of adjacent locations having the same value will be different from read-out signals of adjacent locations having differing values. Hence if such differences occur, i.e. if the read signals of some bit locations have values at an intermediate level between the maximum and minimum levels of other bit locations, misalignment is detected. It is noted that in non correlated data the intermediate levels will occur in substantially 50% of the bit locations due to the fact that the respective neighboring location has a same or different logical value. In an embodiment predefined control patterns having known neighboring bits are included for misalignment detection. A control signal is generated to activate the actuators, and after applying the control signal the read-out signal is again analyzed. In an embodiment the record carrier is provided with optical marks for alignment, and the device is provided with separate optical sensors for detecting the optical marks for generating a misalignment signal.

In an embodiment of the storage system the pitch of the array of sensor elements is larger than the pitch of the array of the bit locations, for example by an integral factor n=2 in one or both planar dimensions. Some stepwise movement of the information carrier part relative to the read-out part is provided to read-out positions in each direction in which the pitch differs to access every bit location. The movement may be provided as indicated above, e.g. by the actuators. Such scanning over small distances by means of micro-mechanic means can make it possible to use media with a higher bit density than the density of the read-out part.

In an embodiment of the record carrier the information plane is provided with position mark patterns that are unique patterns in the information plane within a predefined area of the information carrier. The storage device is provided with a processor for applying techniques of pattern recognition for detection the absolute position of the position mark patterns with respect to the sensor elements array by analyzing the signals detected from the sensor elements. For example the position mark patterns may comprise a large area of material which is larger than any initial mechanical misalignment. The large area is surrounded by a contour without material having a predetermined pattern. Hence some sensor elements will always initially be covered by said large area. By analyzing the surrounding sensor elements the misalignment can be detected easily.

In an embodiment the array of sensor elements is substantially smaller than the information plane, e.g. 4 times smaller. The device is provided with actuators that are arranged for positioning the record carrier or the array of sensor elements at a few, e.g. 4, read-out positions for reading areas of the information plane.

In an embodiment the alignment elements of the record carrier are constituted by oblong protruding guiding bars, and the complementary guiding elements on the device are slots or grooves. The alignment by these elements is effective in one planar dimension. The alignment in the other planar dimension may be provided by a wall or protruding stopping pin on the device. Alternatively there may be no specific stopping position in the second planar dimension, but the information is retrieved from the bit locations while the record carrier is being propelled along that second direction, e.g. by the user pushing the record carrier via a guiding slot. Such constellation is advantageous for one-time reading of data from the record carrier, e.g. in an application like a personal passport carrying biomedical or DNA information for access control at an airport.

FIG. 4b shows a storage device (side view) and record carrier. The storage device has a housing 45 and an opening 43 for receiving a record carrier 40. When coupling the record carrier 40 to the storage device 45 the record carrier is placed on the opening 43. Close contact between the two parts is obtained by pressing (possibly with contact liquid) the read-out array against the information carrier when the slot of the reader is closed. The opening 43 is provided with an interface surface 32 on a read-out unit 30 as described above with reference to FIG. 3, and with alignment elements 42 at the inner end of the opening and outer alignment elements 44 at the entry side of the opening 43. The outer alignment elements 44 are arranged for clamping the record carrier. The record carrier has a protruding alignment element 41 for cooperating with the clamping outer alignment elements 44 on the device for positioning the bit locations near the sensor elements within the near-field working distance between a bit location and the corresponding sensor element during said coupling. The clamping movement may be activated by the force the user applies during entering the record carrier into the opening, or by an actuator.

FIG. 4c shows a record carrier in a cartridge. The record carrier has a cartridge 47 enclosing the information carrier part 10. The cartridge 47 has a movable cover 48 that effectively seals off the information plane from contamination (dust and fingerprints) when the record carrier is not coupled to a storage device. A storage device has an opening mechanism (not shown) for moving the cover aside during said coupling. Several options for slidable covers are known from optical or magnetical recording disc cartridges and cooperating devices.

In an embodiment the cartridge comprises a cleaning pad 46. The pad 46 is located on and/or moved by the cover 48 for wiping the information plane and/or the interface surface when the cover is moved. Alternatively the pad or other cleaning units such as a brush may be placed on the cartridge itself In an embodiment the cartridge is provided with a dust attracting inner layer for attracting any dust particles that may have entered the closed cartridge in spite of the cover 48.

FIG. 5 shows sensor elements at a near field working distance of an information plane. Two sensor elements 54, 56 of the array are shown. Above the sensor elements 54, 56 an information carrier part is shown having a substrate 51 and a layer of a magnetic material 52. At a bit location 53 a protruding portion brings the material close to the sensor element 56 and into its near-field working distance. At the adjacent bit location the material is outside the near-field working distance of the next sensor element 54. The sensor elements are arranged for generating magnetic fields 55, 57, for example as shown by guiding an electric current via a lead 58 beneath the element 56. The magnetic field is influenced by the absence or presence of the magnetic material as shown in the resulting magnetic fields 55,57, which result in a different magnetic direction in a top layer of the sensor element. The direction is detected in sensor elements having a multilayer or single layer stack by using a magneto-resistive effect, for example GMR, AMR or TMR. The TMR type sensor is preferred for resistance matching reasons for the read-only sensor element of this invention.

As shown in the Figure the vicinity of a portion of the magnetic layer on the information carrier forces the field lines of a bias field away from the TMR-element. The material acts as a flux guide: the field lines go through the material instead of through the free layer of the spin-tunnel junction. If the stack of the spin-tunnel junction is designed such that the interlayer magnetostatic coupling results in an antiparallel magnetization configuration if no external magnetic field is applied, the vicinity of a protrusion of the magnetic layer results in a high resistance, while otherwise the bias field will cause a low resistance state. In an embodiment a current carrying conductor is used as field generating strap for the bias field. Alternatively this may be a permanent magnet. Many variants are possible for the bias fields and also stray fields may be used, as will be clear for the person skilled in the art. The bias field in the media can be in the plane of the substrate (as shown in the Figure), but one could alternatively also consider bias fields perpendicular to the substrate resulting in stray fields from the magnetic layer that have components in the plane of the layers of the spin-tunnel junctions. While the given examples use magnetoresistive elements with in-plane sensitivity it is also possible to use elements that are sensitive to perpendicular fields. For a further description of sensors using magnetoresistive effects refer to “Magnetoresistive sensors and memory” by K. -M. H. Lenssen, as published in “Frontiers of Multifunctional Nanosystems”, page 431-452, ISBN 1-4020-0560-1 (HB) or 1-4020-0561-X (PB).

In the storage system data are represented by magnetization directions occurring at a sensor element due to the bit location opposite the sensor on the information plane. The read-out is done by a resistance measurement which relies on a magnetoresistance (MR) phenomenon detected in a multilayer stack. Sensors can be based on the anisotropic magnetoresistance (AMR) effect in thin films. Since the amplitude of the AMR effect in thin films is typically less than 3%, the use of AMR requires sensitive electronics. The larger giant magnetoresistance effect (GMR) has a larger MR effect (5 à15%), and therefore a higher output signal. The magnetic tunnel junctions use a large tunnel magnetoresistance (TMR) effect, and resistance changes up to ≈50% have been shown. Because of the strong dependence of the TMR effect on the bias voltage, the useable resistance change in practical applications is at present around 35%. In general, both GMR and TMR result in a low resistance if the magnetization directions in the multilayer stack are parallel and in a high resistance when the magnetizations are oriented antiparallel. In TMR multilayers the sense current has to be applied perpendicular to the layer planes (CPP) because the electrons have to tunnel through the barrier layer; in GMR devices the sense current usually flows in the plane of the layers (CIP), although a CPP configuration might provide a larger MR effect, but the resistance perpendicular to the planes of these all-metallic multilayers is very small. Nevertheless, using further miniaturization, sensors based on CPP and GMR are possible.

FIG. 6 shows a sensor element in detail. The sensor has a bit line 61 of an electrically conductive material for guiding a read current 67 to a multilayer stack of layers of a free magnetic layer 62, a tunneling barrier 63, and a fixed magnetic layer 64. The stack is build on a further conductor 65 connected via a selection line 68 to a selection transistor 66. The selection transistor 66 couples said read current 67 to ground level for reading the respective bit cell when activated by a control voltage on its gate. The magnetization directions 69 present in the fixed magnetic layer 64 (also called pinned layer) and the free magnetic layer 62 determine the resistance in the tunneling barrier 63, similar to the bit cell elements in an MRAM memory. The magnetization in the free magnetic layer is determined by the material at the bit location opposite the sensor as described above with FIG. 5, when such material is within the near-field working distance indicated by arrow 60.

In an embodiment no additional means are needed to generate the bias field, but the bias field is effectively built-in in the spin-tunnel junction. This might, for example, be accomplished in the following ways. A built-in permanent magnet is achieved by an additional hard-magnetic layer underneath or above the spin-tunnel junction, or by an “over-dimensioned” pinned layer, e.g. an exchange-biased layer, or the hard-magnetic layer in the case of a “pseudo-spin valve like” MR-element. It is important that the resulting magnetostatic coupling dominates any direct exchange coupling between pinned and free layer, as is generally the case for a spin-tunnel junction. The effect of the magnetostatic coupling on the free layer should be reduced sharply when the soft-magnetic layer of the information carrier is close to the element, i.e. inside the near-field working distance. This can be accomplished by making the distance sufficiently small and the thickness of this layer sufficiently large. In an embodiment the material in the information plane is permanent magnetized in a direction parallel to the magnetization direction of the free layer in the sensor element. Because of flux closure protrusions in the information carrier will lead to a reversal of the magnetization of the free layer, provided the coupling to the carrier is stronger than the coupling with the other layers within the MR element.

For the sensor elements, because of the different requirements compared to those for MRAM, the composition and characteristics of the spin-tunnel junctions are adapted compared to those used for MRAM. While for MRAM two stable magnetization configurations (i.e. parallel and antiparallel) are essential for the storage, this does not have to be the case for the proposed sensor element. Here read sensitivity is crucial, while a bi-stable magnetization configuration is in general not relevant. Of course the direction of the reference magnetization, e.g. in the pinned or exchange-biased layer should be invariant. Hence for the free layer, which acts as detection layer, materials with a low coercivity can be chosen.

In an embodiment a number of sensor elements are read at the same time. The addressing of the bit cells is done by means of an array of crossing lines. The read-out method depends on the type of sensor. In the case of pseudo-spin valves a number of cells (N) can be connected in series in the word line, because the resistance of these completely metallic cells is relatively low. This provides the interesting advantage that only one switching element (usually a transistor) is needed per N cells. The associated disadvantage is that the relative resistance change is divided by N. The read-out is done by measuring the resistance of a word line (with the series of cells), while subsequently a small positive plus negative current pulse is applied to the desired bit line. The accompanying magnetic field pulses are between the switching fields of the two ferromagnetic layers; thus the layer with the higher switching field (the sensing layer) will remain unchanged, while the magnetization of the other layer will be set in a defined direction and then be reversed. From the sign of the resulting resistance change in the word line it can be seen whether a ‘0’ or a ‘1’ is stored in the cell at the crossing point the word and the bit line. In an embodiment spin valves with a fixed magnetization direction are used and the data is detected in the other, free magnetic layer. In this case the absolute resistance of the cell is measured. In an embodiment the resistance is measured differentially with respect to a reference cell. This cell is selected by means of a switching element (usually a transistor), which implies that in this case one transistor is required per cell. Besides sensors with one transistor per cell, alternatively sensors without transistors within the cell are considered. The zero-transistor per cell sensor elements in cross-point geometry provide a higher density, but have a somewhat longer read time.

The memory device according to the invention is in particular suitable for the following applications. A first application is a portable device that needs removable memory, e.g. a laptop computer or portable music player. The storage device has low power consumption, and instant access to the data. The record carrier can also be used as a storage medium for content distribution. A further application is a memory that is very well copyright-protected. The protection benefits from the fact that no recordable/rewritable version of the record carrier exists and a consumer reasonably cannot copy the read-only information carrier, and from the fact that without the (correct) bias field reading the information carrier is not possible. For example this type of memory is suitable for game distribution. In contrast to existing solutions it has all the following properties: easily replicable, copy-protected, instant-on, fast access time, robust, no moving parts, low power consumption, etc.

Although the invention has been mainly explained by embodiments using soft magnetic material and flux guidance, any type of near-field interaction can be used, e.g. capacitive coupling. It is noted, that in this document the verb ‘comprise’ and its conjugations do not exclude the presence of other elements or steps than those listed and the word ‘a’ or ‘an’ preceding an element does not exclude the presence of a plurality of such elements, that any reference signs do not limit the scope of the claims, that the invention may be implemented by means of both hardware and software, and that several ‘means’ or ‘units’ may be represented by the same item of hardware or software. Further, the scope of the invention is not limited to the embodiments, and the invention lies in each and every novel feature or combination of features described above.

1. Storage system comprising a record carrier and a storage device,
the record carrier having an information plane that is provided with a pattern of an electromagnetic material constituting an array of bit locations, the presence or absence of said material at the information plane representing a value of a bit location, and
the device having an interface surface for cooperating with the information plane, which interface surface is provided with an array of electromagnetic sensor elements that are sensitive to the presence of said electromagnetic material within a near-field working distance,
which record carrier can be coupled to and removed from the storage device, and
the system having alignment means for positioning the bit locations near the sensor elements within the near-field working distance between a bit location and the corresponding sensor element during said coupling.

2. Record carrier for use in the system as claimed in claim 1, the record carrier comprising an information plane on a substrate that is provided with a pattern of an electro-magnetic material constituting an array of bit locations, characterized in that the presence or absence of said material at the information plane represents a value of a bit location, and in that the record carrier comprises alignment means for positioning the bit locations near the sensor elements within a near-field working distance between a bit location and the corresponding sensor element during said coupling.

3. Record carrier as claimed in claim 2, wherein the pattern at the information plane is constituted by a layer of the electromagnetic material on the substrate having protruding portions or depressed portions that bring the electromagnetic material of the layer either outside or inside the near-field working distance.

4. Record carrier as claimed in claim 2, wherein the pattern at the information plane is constituted by the substrate covered by a pattern of areas of the electromagnetic material, or by the presence or absence of particles of said material embedded in a substrate.

5. Record carrier as claimed in claim 2, 3 or 4, wherein the electromagnetic material has a soft magnetic property for being detectable by said sensor elements, or wherein the electromagnetic material has an electrically conductive property for being detectable by said sensor elements.

6. Record carrier as claimed in claim 2, 3 or 4, wherein the substrate is of a flexible material for allowing positioning of the bit locations near the sensor elements within the near-field working distance between a bit location and the corresponding sensor element.

7. Record carrier as claimed in claim 2, wherein the record carrier comprises a cartridge having an opening for exposing the information plane when coupled to the device and a cover for closing the opening when removed from the device.

8. Record carrier as claimed in claim 7, wherein the cartridge comprises cleaning means (46) for cleaning the information plane and/or the interface surface.

9. Record carrier as claimed in claim 2, wherein the alignment means comprise mechanical guiding elements for cooperating with complementary mechanical receiving elements of the storage device.

10. Storage device for use in the system as claimed in claim 1, characterized in that the device comprises
an interface surface for cooperating with the information plane, which interface surface is provided with an array of electro-magnetic sensor elements that are sensitive to the presence of said electromagnetic material, and
alignment means for positioning the sensor elements near the bit locations within a near-field working distance between a sensor element and the corresponding bit location during said coupling.

11. Device as claimed in claim 10, wherein the sensor elements are arranged for generating an electromagnetic field and detecting the presence of said electro-magnetic material in at least one of the following ways:
generating a magnetic field and detecting the magnetic field as influenced by the presence of absence of the electromagnetic material via a soft magnetic property; or
generating an electrical field and detecting the electrical field as influenced by the presence or absence of the electromagnetic material via a capacitive coupling; or
generating a fluctuating magnetic field and detecting the magnetic field as influenced by the presence of absence of the electromagnetic material via eddy currents.

12. Device as claimed in claim 10, wherein the alignment means comprise an actuator for positioning the sensor elements and/or the record carrier.

13. Device as claimed in claim 12, wherein the actuator for positioning the sensor elements and/or the record carrier is controlled in dependence of a read-out signal from the electro-magnetic elements.

14. Device as claimed in claim 10, wherein the array of sensor elements has substantially less sensor elements then the total number of bit locations of the record carrier, and the alignment means) are arranged for positioning said array or the record carrier at different alignment positions that in combination cover the total number of bit locations.

15. Device as claimed in claim 10, wherein the alignment means comprise mechanical receiving elements for cooperating with complementary mechanical guiding elements of the record carrier.

16. Device as claimed in claim 10, wherein the alignment means comprise means for generating an attracting field for attracting the record carrier to the interface surface, in particular an electrostatic field.
